(19) United States
(12) Patent Application Publication
(10) Pub. No.: US 2026/0271371 A1
(43) Pub. Date: Sep. 10, 2026

(54) GATE OXIDE STACK FOR SIC MOSFET

(71) Applicant: Microchip Technology Incorporated, Chandler, AZ (US)

(72) Inventors: Sami Alexandre El Hageali, Castle Rock, CO (US); Yogesh Kumar Sharma, Colorado Springs, CO (US); Sergey Maximenko, Colorado Springs, CO (US); Shesh Mani Pandey, Gilbert, AZ (US); Bruce Odekirk, Portland, OR (US); Michael Don Whiteman, Woodland Park, CO (US); Kevin Speer, Bentonville, AR (US)

(73) Assignee: Microchip Technology Incorporated, Chandler, AZ (US)

(21) Appl. No.: 19/250,679

(22) Filed: Jun. 26, 2025

Related U.S. Application Data
(60) Provisional application No. 63/769,389, filed on Mar. 10, 2025.

(51) Int. Cl. H10D 64/68; H10D 30/01; H10D 30/66; H10D 64/01; H10P 14/60; H10D 62/832

(52) U.S. Cl. CPC H10D 64/685; H10D 30/0297; H10D 30/668; H10D 64/01366; H10D 64/027; H10P 14/6336; H10P 14/6339; H10P 14/6526; H10P 14/6529; H10D 62/8325

(57) ABSTRACT

A trench metal oxide semiconductor field-effect transistor with a gate oxide stack, and a method of making a trench metal oxide semiconductor field-effect transistor with a gate oxide stack. A first layer of gate oxide is deposited on a surface of the trench using an atomic layer deposition or molecular vapor deposition process. A second layer of gate oxide is deposited on the first layer using a plasma-enhanced chemical vapor deposition process. The first and second layers of gate oxide are thermally annealed in a non-oxidizing atmosphere with a forming gas. Prior to depositing the first layer, the surface of the trench may be etched, an initial layer of thermal oxide may be deposited, and the initial layer may be nitridized or thermally annealed. If the initial layer is deposited on the surface of the trench, then the first layer is deposited on the initial layer.

### RELATED APPLICATION

The present U.S. non-provisional patent application is related to and claims priority benefit of an earlier-filed U.S. provisional patent application titled "Gate Oxide Stack for Trench SiC MOSFET," Serial No. 63/769,389, filed Mar. 10, 2025. The entire content of the identified earlier-filed application is incorporated by reference as if fully set forth herein.

### FIELD

The present disclosure relates to metal oxide semiconductor field-effect transistors and methods of making them, and more particularly, the various examples described herein concern a metal oxide semiconductor field-effect transistor with a gate oxide stack, and a method of making a metal oxide semiconductor field-effect transistor with a gate oxide stack.

### BACKGROUND

A metal-oxide-semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY

Examples provide a trench MOSFET with a gate oxide stack, and a method of making a trench MOSFET with a gate oxide stack. Broadly, a "gate oxide stack" comprises multiple layers of dielectric material(s) that separate a gate from a channel in a field-effect transistor (FET). Examples advantageously provide a higher-quality silicon dioxide (SiO2) gate oxide stack with a better crystallographic interface that results in a lower density of interface states, provides better thermal stability and lower gate leakage, and exhibits reduce threshold voltage shifts and improved device stability. Although described herein with regard to a trench MOSFET, it will be understood that the technology of the present examples can also be used to provide a gate oxide stack for a planar MOSFET.

In an example, a method of making a trench FET may include the operations set forth below. The trench FET may include a trench in a volume of semiconductor material. A first layer of gate oxide may be deposited on a surface of the trench. A second layer of gate oxide may be deposited on the first layer of gate oxide using a plasma-enhanced chemical vapor deposition (PECVD) process. The first and second layers of gate oxide may be thermally annealed.

The preceding example may further include any one or more of the following features. The first layer of gate oxide may be deposited using an atomic layer deposition (ALD) process or using a molecular vapor deposition (MVD) process. The operation of thermally annealing the first and second layers of gate oxide may be performed in a non-oxidizing atmosphere with a forming gas (FG) for between one (1) and two (2) hours at between one thousand fifty (1050) and one thousand two hundred (1200) degrees Celsius. The first and second layers of gate oxide may be between six hundred (600) and eight hundred (800) Angstroms in total thickness. The method may further include providing an initial layer of thermal oxide on the surface of the trench before depositing the first layer of gate oxide on the initial layer of thermal oxide, and performing on the initial layer of thermal oxide an operation such as nitridizing or thermal annealing. The initial layer of thermal oxide may be between eight (8) and twelve (12) Angstroms in thickness.

In another example, a method of making a trench MOSFET may include the following operations. A trench may be created in a volume of semiconductor material, and the trench may include a surface. The surface of the trench may be etched. An initial layer of thermal oxide may be provided on the surface of the trench. An operation such as nitridizing or thermal annealing may be performed on the initial layer of thermal oxide. A first layer of gate oxide may be deposited on the initial layer of thermal oxide. A second layer of gate oxide may be deposited on the first layer of gate oxide using a PECVD process. The first and second layers of gate oxide may be thermally annealed.

The preceding example may further include any one or more of the following features. The first layer of gate oxide may be deposited using an ALD process or using an MVD process. The operation of thermally annealing the first and second layers of gate oxide may be performed in a non-oxidizing atmosphere with an FG for between one (1) and two (2) hours at between one thousand fifty (1050) and one thousand two hundred (1200) degrees Celsius. The initial layer of thermal oxide may be between eight (8) and twelve (12) Angstroms in thickness. The first and second layers of gate oxide may be between six hundred (600) and eight hundred (800) Angstroms in total thickness.

In another example, a trench FET may include a volume of semiconductor material, a source, a trench, a first layer of gate oxide, and a second layer of gate oxide. The volume of semiconductor material may include a first end and a second end. The source may be located at the first end, and the trench may be located adjacent to the source and extend into the volume of semiconductor material. The trench may include a surface. The first layer of gate oxide may be deposited on the surface of the trench. The second layer of gate oxide may be deposited on the first layer of gate oxide via a PECVD process. The first and second layers of gate oxide may be thermally annealed.

The preceding example may further include any one or more of the following features. The first and second layers of gate oxide may be between six hundred (600) and eight hundred (800) Angstroms in total thickness. The trench FET may further include an initial layer of thermal oxide on the surface of the trench beneath the first layer of gate oxide. The initial layer of thermal oxide may be nitridized. The initial layer of thermal oxide may be thermally annealed. The initial layer of thermal oxide may be between eight (8) and twelve (12) Angstroms in thickness.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional view of a first example of a trench MOSFET with a gate oxide stack, wherein the gate oxide stack includes an initial layer of thermal oxide;

FIG. 2 is a cross-sectional view of a trench region of the first trench MOSFET of FIG. 1, showing the gate oxide stack including the initial layer of thermal oxide;

FIG. 3 is a cross-sectional view of a second example of a trench MOSFET with a gate oxide stack, wherein the gate oxide stack does not include the initial layer of thermal oxide;

FIG. 4 is a cross-sectional view of a trench region of the second trench MOSFET of FIG. 3, showing the gate oxide stack not including the initial layer of thermal oxide; and

FIG. 5 is a flowchart of operations in an example method of making a trench MOSFET with a gate oxide stack, such as the example trench MOSFETs of FIGS. 1 and 3.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples. The illustrations presented herein are not meant to be actual views of any particular method, system, device, or structure, but are merely idealized representations that are employed to describe the examples of the present disclosure. Similar structures or components in the various drawings may retain the same or similar numbering for the convenience of the reader; however, any similarity in numbering does not necessarily mean that the structures or components are necessarily identical in size, composition, configuration, or any other property. Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation. It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

The reliability and performance of silicon carbide (SiC) MOSFETs can be negatively affected by interface trap defects at the interface of the SiO2 gate oxide, or gate dielectric, and the silicon carbide (SiC or 4H-SiC) semiconductor material. In trench-type devices, thermal oxidation is generally not used to form the SiO2 due both to non-uniformities in growth on the horizontal and vertical surfaces of the trench and to longer processing time. One solution is to use full-thickness ALD along with nitrogen passivation.

Examples provide a trench MOSFET with a gate oxide stack (i.e., multiple layers of dielectric material(s)), and a method of making a trench MOSFET with a gate oxide stack. Examples advantageously provide a higher-quality silicon dioxide (SiO2) gate oxide stack with a better crystallographic interface that results in a lower density of interface states, provides better thermal stability and lower gate leakage, and exhibits reduce threshold voltage shifts and improved device stability. Although described herein with regard to a trench MOSFET, it will be understood that the technology of the present examples can also be used to provide a gate oxide stack for a planar MOSFET.

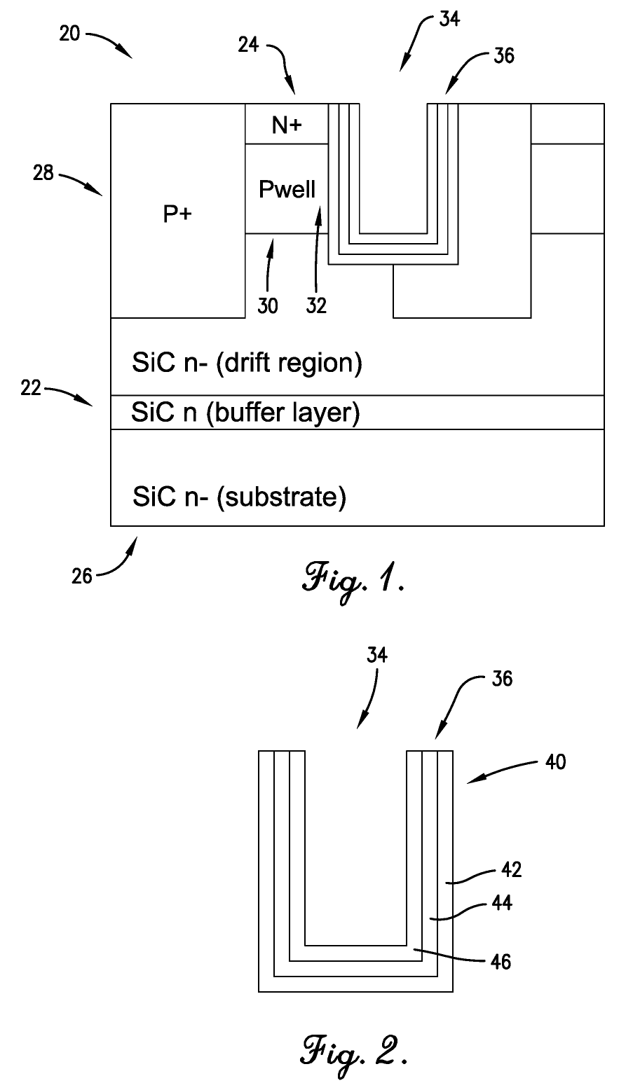

Referring to FIGS. 1 and 2, a first example of a trench MOSFET 20 with a gate oxide stack is shown including a volume of semiconductor material 22, a source 24, a drain 26, a body 28, a well 30, a channel 32, a trench 34, and the gate oxide stack 36. The volume of semiconductor material 22 may include a first end and a second end. The semiconductor material 22 may be or include SiC, such as 4H-SiC, and may include, for example, an N- drift region and an N+ buffer layer. The source 24 may be located at the first end of the volume of semiconductor material 22, and may provide an entrance for charge carriers. The source 24 may be or include N+ material. The drain 26 may be located spaced apart from the source 24 (e.g., at the second end) and may provide an exit for the charge carriers. The drain 26 may be or include an N+ substrate material. The body 28 may facilitate controlling the movement of charge carriers. The body 28 may be or include a P+ material. The well 30 facilitates forming the channel 30. The well 30 may be or include P-type material. The channel 32 may be a region between the source 24 and the drain through which the charge carriers move. The trench 34 may be located adjacent to the source 24 and extend into the volume of semiconductor material 22. The trench 34 may include a surface 40, and the surface 40 may include approximately vertical sidewall and approximately horizontal bottom components. The surface 40 may be etched before any gate oxide is formed.

The gate oxide stack 36 may include multiple layers of gate oxide on the surface 40 of the trench 34. In more detail, the gate oxide stack 36 may include an initial thermal oxide layer of gate oxide 42, a first layer of gate oxide 44, and a second layer of gate oxide 46. The initial thermal oxide layer 42 may be provided on the etched surface 40. In some instances, the initial thermal oxide layer 42 may be formed by implanting silicon (Si) and then thermally oxidizing the Si to form SiO2, although it is within the ambit of other examples to simply thermally oxidize the volume of semiconductor material itself. The initial thermal oxide layer 42 may be relatively thin, such as, for example, approximately between eight (8) and twelve (12) Angstroms, or approximately ten (10) Angstroms. The initial thermal oxide layer 42 may function to both provide a smoother surface 40 and passivate dangling bonds and traps within the semiconductor material. The initial thermal oxide layer 42 may be nitridized or thermally annealed. Nitridizing the initial thermal oxide layer 42 may involve a nitrogen passivation process. Thermally annealing the initial thermal oxide layer 42 may be performed in a forming gas (FG). An FG is a mixture of nitrogen and hydrogen and is used to passivate semiconductor surfaces and reduce surface oxides on metals during the thermal annealing process.

The first layer of gate oxide 44 may be deposited or otherwise provided on the initial thermal oxide layer 42. The first layer of gate oxide 44 may be deposited using an atomic layer deposition (ALD) process or a molecular vapor deposition (MVD) process. The second layer of gate oxide 46 may be deposited or otherwise provided on the first layer of gate oxide 44 using a plasma-enhanced chemical vapor deposition (PECVD) process. The first and second layers of gate oxide 44, 46 may be thermally annealed. The operation of thermally annealing the first and second layers of gate oxide 44, 46 may be performed in a non-oxidizing atmosphere with an FG for approximately between one (1) and two (2) hours at approximately between one thousand fifty (1050) and one thousand two hundred (1200) degrees Celsius. If the initial thermal oxide 42 is undesirably thinner on some portion (e.g., the bottom) and thicker on another portion (e.g., the side) of the surface 40, then the subsequently applied first and/or second layers of gate oxide 44, 46 may be adapted to compensate for the difference in thickness. The total thickness of the gate oxide stack may be approximately between six hundred (600) and eight hundred (800) Angstroms, or approximately seven hundred (700) Angstroms.

Additional components may be incorporated as desired. For example, a gate material (e.g., polysilicon) may be deposited, formed, or otherwise provided in the gate-oxide-lined trench 34 to provide a gate (not shown).

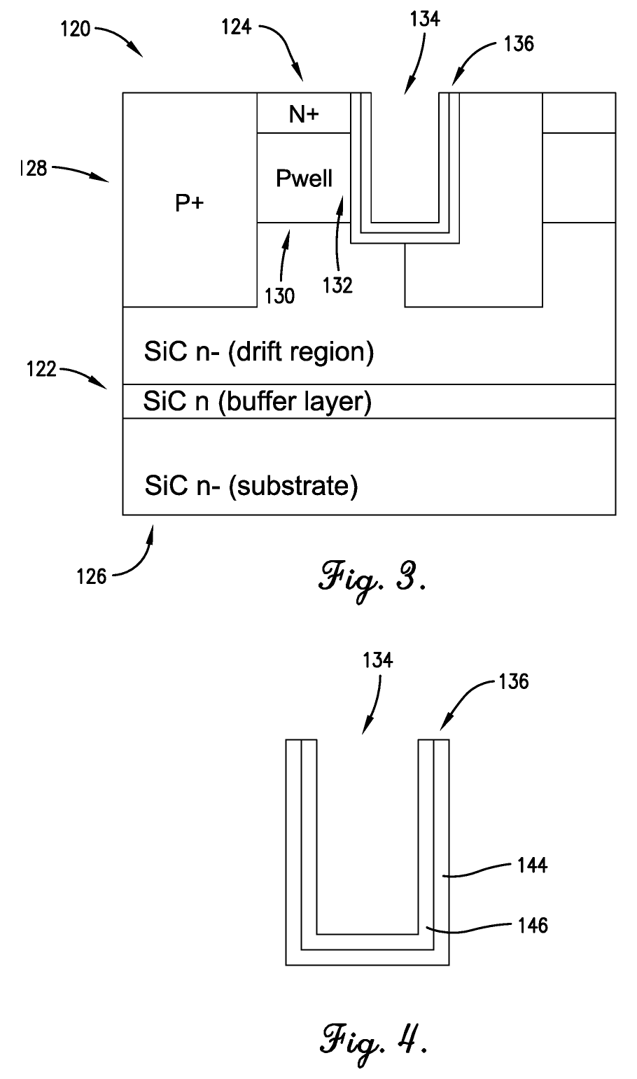

Referring to FIGS. 3 and 4, a second example of a trench MOSFET 120 with a gate oxide stack is shown including a volume of semiconductor material 122, a source 124, a drain 126, a body 128, a well 130, a channel 132, a trench 134 including a surface 140, and a gate oxide stack 136. The second example trench MOSFET 120 may be substantially similar or identical to the first example trench MOSFET 20 except that the gate oxide stack 136 may include the first and second gate oxide layers 144, 146, and may not include the initial thermal oxide layer.

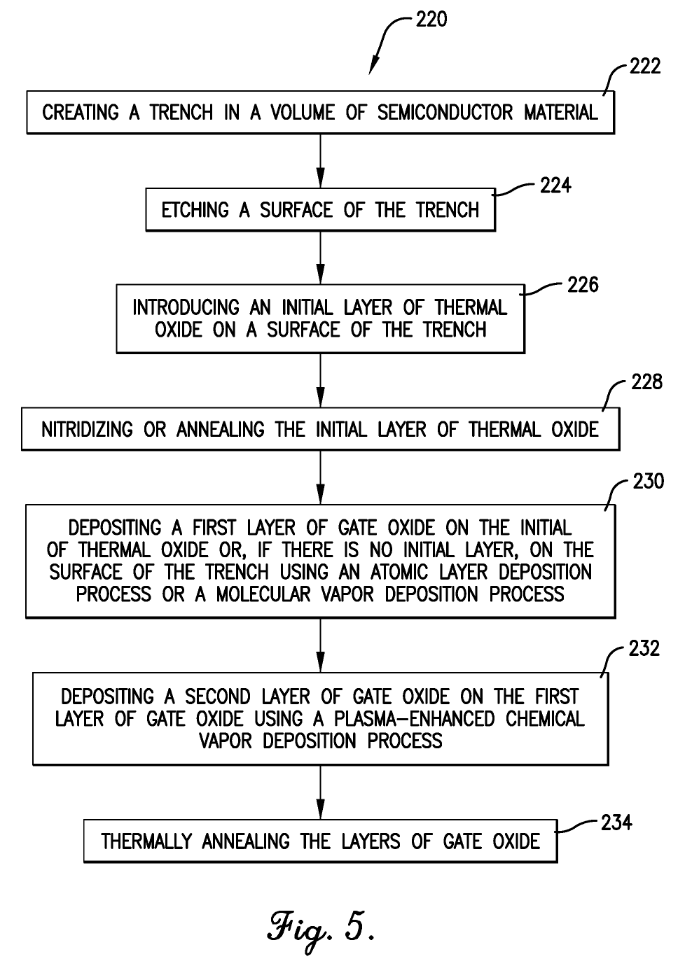

Referring to FIG. 5, an example of a method 220 for making a trench MOSFET with a gate oxide stack, such as the example trench MOSFETs 20, 120 of FIGS. 1 and 3, may include the operations set forth below. The trench MOSFET 20, 120 may include a volume of semiconductor material 22, 122. Other components, such as the source 24, 124, drain 26, 126, body 28, 128, and well 30, 130, may be formed as needed using substantially any suitable process (e.g., suitable stepwise masking and ion implantation).

A trench 34, 134 may be created in the volume of semiconductor material 22,122, as shown in 222 (e.g., by a suitable etching process). A surface 40, 140 of the trench 34, 134 may be pre-etched (before any gate oxide is formed), as shown in 224. An initial thermal oxide layer 42 may be introduced on the etched surface of the trench 34, as shown in 226. The initial thermal oxide layer 42 may be relatively thin, such as, for example, approximately between eight (8) and twelve (12) Angstroms, or approximately 10 Angstroms. The initial thermal oxide layer 42 may both provide a smoother surface 40 of the trench 34 and passivate dangling bonds and traps within the semiconductor material. The initial thermal oxide layer 42 may be nitridized or thermally annealed, 228. The operation of nitridizing may involve a nitrogen passivation process, and the operation of thermal annealing may be performed in an FG. This allows for a surface trap passivation along with an efficient carbon cluster release. The operations of etching the surface and introducing and nitridizing or thermal annealing the initial thermal oxide layer 42, as shown in 224, 226, and 228, may be included to make the first example MOSFET 20 or eliminated to make the second example MOSFET 120, as desired.

A first layer of gate oxide 44, 144 may be deposited or otherwise provided on the initial thermal layer of gate oxide 42, as shown in 230. If the initial layer of thermal oxide 42 is not introduced, then the first layer of gate oxide 44, 144 may be provided directly on the surface 140 of the trench 130. The first gate oxide layer 44, 144 may be deposited using an ALD process or an MVD process. ALD/MVD provides improved thickness control and uniformity across complex geometries, improved conformality even with high aspect ratios geometries, and higher purity and fewer defects compared to other deposition methods. This results in improved interface quality, reduced traps, and enhanced overall device performance due to an atomic interaction rate that passivates a substantial majority of the traps.

A second gate oxide layer 46, 146 may be deposited or otherwise provided on the first gate oxide layer 44, 144 using a PECVD process, as shown in 232. It may be desirable for trench devices to have a thick bottom gate oxide. Using PECVD for the remaining bulk layer benefits from its fast deposition rate and coverage, thereby improving throughput. Further, using PECVD benefits non-conformal designs. Using ALD/MVD in conjunction with PECVD for gate oxide growth in SiC trench devices combines the desirable features of both processes, resulting in improved deposition rates and enhanced oxide properties, as well as optimizing both the interface and bulk properties of the gate oxide.

If the initial thermal oxide 42 is applied and is undesirably thinner on some portion (e.g., the bottom) of the surface 40, 140 and thicker on another portion (e.g., the side) of the surface 40, 140, then the subsequent operations of applying the first and/or second layers of gate oxide 44, 46 may be adapted to compensate for the difference in thickness, as desired. The total thickness of the gate oxide stack may be approximately between six hundred (600) and eight hundred (800) Angstroms, or approximately seven hundred (700) Angstroms.

The first and second gate oxide layers 44, 144, 46, 146 may be thermally annealed, as shown in 234. The operation of thermally annealing the first and second gate oxide layers 44, 144, 46, 146 may be performed in a non-oxidizing atmosphere with an FG for approximately between one (1) and two (2) hours at approximately between one thousand fifty (1050) and one thousand two hundred (1200) degrees Celsius. Thermal annealing provides improvements to the ALD/MVD layer 44, 144 with regard to flatband voltage, hysteresis, and positive mobile charge density near the interface. The use of FG provides a more Si-rich interface, thereby decreasing the ratio of carbon (C) to Si which is beneficial for passivation and interface trap density. Thermal annealing with an FG also provides an increase in hydrogen (H) concentration near the interface of the thermally annealed sample when compared to a thermal sample, suggesting that the improvement in electrical performance is due to H passivation of trap states at the oxide-semiconductor interface. Thermal annealing in an FG also breaks down complexes into Si dangling bonds, which can then be easily passivated. Typically, a more stoichiometric interface allows compositionally greater hydrogen passivation. Hence, passivation in ALD/MVD-deposited SiO2/4H-SiC becomes similar to the well-known thermal SiO2/Si system.

Additional processing may be performed as desired. For example, a gate material (e.g., polysilicon) may be deposited or otherwise provided in the gate-oxide-lined trench 34, 134 to provide a gate (not shown).

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between ten to the power of eighteen (10^18) and ten to the power of twenty-two (10^22); doping concentrations for channel and threshold forming implants may be approximately between ten to the power of sixteen (10^16) and ten to the power of seventeen (10^17); doping concentrations for shielding implants may be approximately between ten to the power of seventeen (10^17) and ten to the power of nineteen (10^19); and doping concentrations for conductivity improvement implants (e.g., N- doping in the junction field-effect transistor neck region of a metal oxide semiconductor field-effect transistor) may be approximately between ten to the power of sixteen (10^16) and ten to the power of seventeen (10^17). Relatedly, a structure or region may contain two or more different doping doses. For example, one with ordinary skill in the art will recognize that some Pwells may contain a lower dose Pwell portion and a higher dose unclamped inductive switching portion.

Additionally, although only one or a few instances of a device or apparatus may be described herein, it will be appreciated that some applications may involve many such devices or apparatuses, which may be different from, substantially similar to, or identical to the described device or apparatus, and which may be arranged (e.g., in an array) on a larger extension of the volume of semiconductor material. In that light, references to a right or left side of a volume of semiconductor material may be to the conceptual limit of a particular unit cell and not to an actual physical end of the material.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A method of making a trench field-effect transistor, the trench field-effect transistor including a trench in a volume of semiconductor material, the method comprising:
depositing a first layer of gate oxide on a surface of the trench;
depositing a second layer of gate oxide on the first layer of gate oxide using a plasma-enhanced chemical vapor deposition process; and
thermally annealing the first and second layers of gate oxide.

2. The method of claim 1, wherein the first layer of gate oxide is deposited using an atomic layer deposition process.

3. The method of claim 1, wherein the first layer of gate oxide is deposited using a molecular vapor deposition process.

4. The method of claim 1, wherein the operation of thermally annealing the first and second layers of gate oxide is performed in a non-oxidizing atmosphere with a forming gas for between one (1) and two (2) hours at between one thousand fifty (1050) and one thousand two hundred (1200) degrees Celsius.

5. The method of claim 1, wherein the first and second layers of gate oxide are between six hundred (600) and eight hundred (800) Angstroms in total thickness.

6. The method of claim 1, further including –
providing an initial layer of thermal oxide on the surface of the trench;
performing on the initial layer of thermal oxide an operation selected from the group consisting of: nitridizing and thermal annealing; and
depositing the first layer of gate oxide on the initial layer of thermal oxide.

7. The method of claim 6, wherein the initial layer of thermal oxide is between eight (8) and twelve (12) Angstroms in thickness.

8. A method of making a trench metal oxide semiconductor field-effect transistor, the method comprising:
creating a trench in a volume of semiconductor material, the trench including a surface;
etching the surface of the trench;
providing an initial layer of thermal oxide on the surface of the trench;
performing on the initial layer of thermal oxide an operation selected from the group consisting of: nitridizing and thermal annealing;
depositing a first layer of gate oxide on the initial layer of thermal oxide;
depositing a second layer of gate oxide on the first layer of gate oxide using a plasma-enhanced chemical vapor deposition process; and
thermally annealing the first and second layers of gate oxide.

9. The method of claim 8, wherein the first layer of gate oxide is deposited using an atomic layer deposition process.

10. The method of claim 8, wherein the first layer of gate oxide is deposited using a molecular vapor deposition process.

11. The method of claim 8, wherein the operation of thermally annealing the first and second layers of gate oxide is performed in a non-oxidizing atmosphere with a forming gas for between one (1) and two (2) hours at between one thousand fifty (1050) and one thousand two hundred (1200) degrees Celsius.

12. The method of claim 8, wherein the initial layer of thermal oxide is between eight (8) and twelve (12) Angstroms in thickness.

13. The method of claim 8, wherein the first and second layers of gate oxide are between six hundred (600) and eight hundred (800) Angstroms in total thickness.

14. A trench field-effect transistor comprising:
a volume of semiconductor material including a first end and a second end;
a source located at the first end of the volume of semiconductor material;
a trench located adjacent to the source and extending into the volume of semiconductor material, the trench including a surface;
a first layer of gate oxide deposited on the surface of the trench; and
a second layer of gate oxide deposited on the first layer of gate oxide, the second layer of gate oxide deposited via plasma-enhanced chemical vapor deposition process,
wherein the first and second layers of gate oxide are thermally annealed.

15. The trench field-effect transistor of claim 14, wherein the first and second layers of gate oxide are between six hundred (600) and eight hundred (800) Angstroms in total thickness.

16. The trench field-effect transistor of claim 14, further including an initial layer of thermal oxide on the surface of the trench beneath the first layer of gate oxide.

17. The trench field-effect transistor of claim 16, wherein the initial layer of thermal oxide is nitridized.

18. The trench field-effect transistor of claim 16, wherein the initial layer of thermal oxide is thermally annealed.

19. The trench field-effect transistor of claim 16, wherein the initial layer of thermal oxide is between eight (8) and twelve (12) Angstroms in thickness.
